(19) United States
(12) Patent Application Publication
(10) Pub. No.: US 2007/0025404 A1
(43) Pub. Date: Feb. 1, 2007

(54) OPTICAL ELEMENT AND METHOD FOR MANUFACTURING THE SAME

(75) Inventor: Tetsuo HIRAMATSU, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/458,399

(22) Filed: Jul. 19, 2006

(30) Foreign Application Priority Data
Jul. 29, 2005 (JP) 2005-221275

(51) Int. Cl. H01S 5/00

(52) U.S. Cl. 372/50.1

(57) ABSTRACT

An optical element includes a surface-emitting type semiconductor laser, a photodetector element that detects a part of laser light emitted from the surface-emitting type semiconductor laser, and a light-receiving element that receives laser light from outside. The photodetector element has a first photoabsorption layer formed above a substrate. The surface-emitting type semiconductor laser has a first mirror formed above the first photoabsorption layer, an active layer formed above the first mirror, and a second mirror formed above the active layer. The light-receiving element has a second photoabsorption layer formed above the second mirror.

The entire disclosure of Japanese Patent Application No. 2005-221275, filed Jul. 29, 2005 is expressly incorporated by reference herein.

### BACKGROUND

1. Technical Field

The present invention relates to optical elements and methods for manufacturing the same.

2. Related Art

A surface-emitting type semiconductor laser has characteristics in which its light output changes depending on the ambient temperature and other conditions. For this reason, an optical module that uses a surface-emitting type semiconductor laser may be equipped with a photodetector element that detects a part of laser light emitted from the surface-emitting type semiconductor laser to thereby monitor its light output value. For example, Japanese Laid Open Patent Application JP-A-10-135568 describes an optical element with a three-terminal structure in which a surface-emitting type laser and a detector element share a common electrode.

### SUMMARY

In accordance with an advantage of some aspects of the present invention, there are provided optical elements that can receive not only light for optical monitoring, but also light transmitted from outside, and methods for manufacturing the same.

An optical element in accordance with an embodiment of the invention includes a surface-emitting type semiconductor laser, a photodetector element that detects a part of laser light emitted from the surface-emitting type semiconductor laser, and a light-receiving element that receives laser light from outside, wherein the photodetector element has a first photoabsorption layer formed above a substrate, the surface-emitting type semiconductor laser has a first mirror formed above the first photoabsorption layer, an active layer formed above the first mirror, and a second mirror formed above the active layer, and the light-receiving element has a second photoabsorption layer formed above the second mirror.

Because the optical element in accordance with the present embodiment includes the surface-emitting type semiconductor laser, the photodetector element and the light-receiving element, the optical element can receive not only light to be monitored, but also light transmitted from outside. Also, the optical element has the photodetector element provided below the surface-emitting type semiconductor laser, and the light-receiving element provided above the surface-emitting type semiconductor laser, the photodetector element can correctly monitor light emitted from the surface-emitting type semiconductor laser, and the light-receiving element can receive light transmitted from outside with good coupling efficiency.

In the optical element in accordance with an aspect of the present embodiment, the second photoabsorption layer may be formed around an emission surface of the surface-emitting type semiconductor laser.

As a result, the light-receiving element can be prevented from absorbing light emitted from the surface-emitting type semiconductor laser.

In the optical element in accordance with an aspect of the present embodiment, the surface-emitting type semiconductor laser may further include an electrode having an aperture section above the second mirror, and the second photoabsorption layer may be formed around the electrode.

As a consequence, the light-receiving element can be prevented from absorbing light emitted from the surface-emitting type semiconductor laser.

In the optical element in accordance with an aspect of the present embodiment, the surface-emitting type semiconductor laser may further include a current constricting layer in the first mirror or the second mirror, and the second photoabsorption layer may be formed above the current constricting layer.

In the optical element in accordance with an aspect of the present embodiment, the surface-emitting type semiconductor laser may have a columnar section that is composed of a first mirror, an active layer and a second mirror and functions as a resonator, and the light-receiving element may be formed above the columnar section.

In the optical element in accordance with an aspect of the present embodiment, the surface-emitting type semiconductor laser may have a columnar section that is composed of a first mirror, an active layer and a second mirror and functions as a resonator, and the light-receiving element may be formed around the columnar section as viewed in a plan view.

The optical element in accordance with an aspect of the present embodiment may further include a base section that is formed around the columnar section and includes layers in common with the first mirror, the active layer and the second mirror, and the light-receiving element may be formed above the base section.

The optical element in accordance with an aspect of the present embodiment may have an emission surface around the second photoabsorption layer.

In the optical element in accordance with an aspect of the present embodiment, the surface-emitting type semiconductor laser may have an electrode having an aperture section above the second mirror, and the light-receiving element may be formed at the aperture section of the electrode.

The optical element in accordance with an aspect of the present embodiment may further include an optical member formed above the light-receiving element.

The optical element in accordance with an aspect of the present embodiment may further include an optical member formed above the emission surface of the surface-emitting type semiconductor laser.

The optical element in accordance with an aspect of the present embodiment may further include a common electrode that drives the photodetector element and also drives the surface-emitting type semiconductor laser.

In the optical element in accordance with an aspect of the present embodiment, a designed wavelength of laser light that is emitted by the surface-emitting type semiconductor laser may be different from a designed wavelength of laser light that is received by the light-receiving element. It is noted that the designed wavelength of the surface-emitting type semiconductor laser is a wavelength of light with the maximum intensity among light generated by the surface-emitting type semiconductor laser. Also, the designed wavelength of the light-receiving element is a wavelength of light with the maximum intensity among laser light that is received by the light-receiving element. It is noted that a designed wavelength of the photodetector element is the same as the designed wavelength of the surface-emitting type semiconductor laser.

The optical element in accordance with an aspect of the present embodiment may further include an isolation layer formed between the second mirror and the second photoabsorption layer.

A method for manufacturing an optical element in accordance with an embodiment of the invention pertains to a method for manufacturing an optical element having a surface-emitting type semiconductor laser, a photodetector element that detects a part of laser light emitted from the surface-emitting type semiconductor laser, and a light-receiving element that receives laser light from outside, the method including the steps of:

laminating layers of a semiconductor multilayer film for forming, from a substrate side, a first photoabsorption layer included in the photodetector element, a first mirror, an active layer and a second mirror included in the surface-emitting type semiconductor laser, and a second photoabsorption layer included in the light-receiving element;

forming an emission surface by exposing an upper surface of the surface-emitting type semiconductor laser by patterning the second photoabsorption layer; and

forming a resonator by patterning the first mirror, the active layer and at least a part of the second mirror.

### BRIEF DESCRIPTION OF THE DRAWINGS

FIG. 1 schematically shows a cross-sectional view of an optical element in accordance with an embodiment of the invention.

FIG. 2 schematically shows a plan view of the optical element in accordance with the embodiment of the invention.

FIG. 3 is a cross-sectional view schematically showing a step of a method for manufacturing an optical element in accordance with an embodiment of the invention.

FIG. 4 is a cross-sectional view schematically showing a step of the method for manufacturing an optical element in accordance with the embodiment of the invention.

FIG. 5 is a cross-sectional view schematically showing a step of the method for manufacturing an optical element in accordance with the embodiment of the invention.

FIG. 6 schematically shows a cross-sectional view of an optical element in accordance with a first modified example of the embodiment of the invention.

FIG. 7 schematically shows a plan view of the optical element in accordance with the first modified example.

FIG. 8 schematically shows a cross-sectional view of an optical element in accordance with a second modified example of the embodiment of the invention.

FIG. 9 schematically shows a plan view of the optical element in accordance with the second modified example.

FIG. 10 schematically shows a cross-sectional view of an optical element in accordance with a third modified example of the embodiment of the invention.

### DESCRIPTION OF EXEMPLARY EMBODIMENTS

Preferred embodiments of the invention are described below with reference to the accompanying drawings.

1. Structure of Optical Element

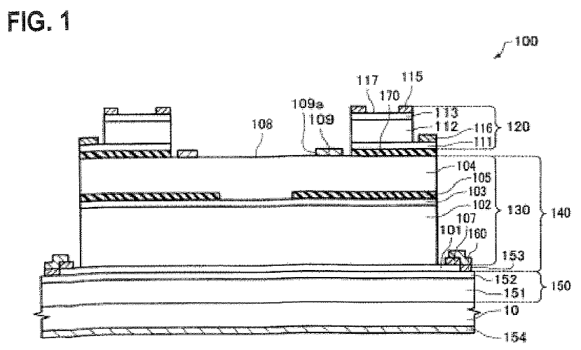

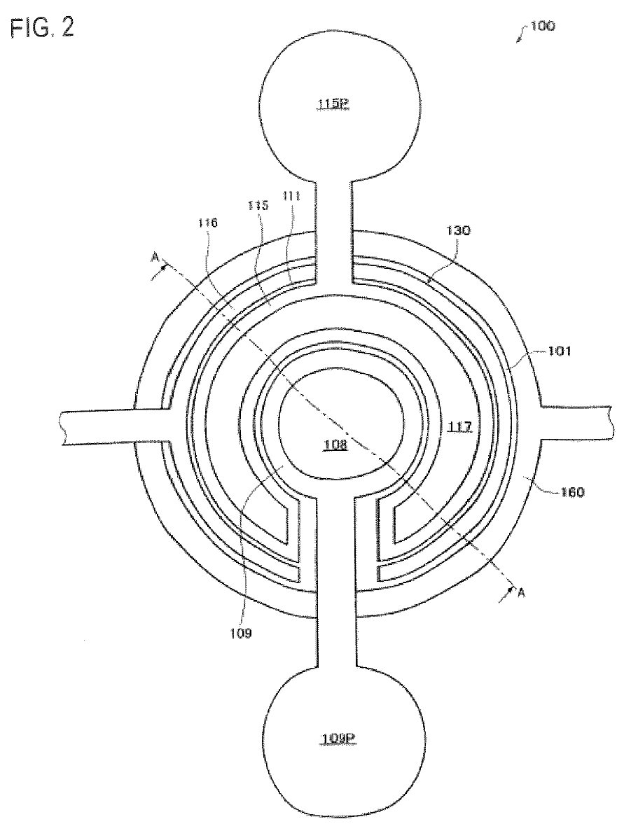

FIG. 1 schematically shows a cross-sectional view of an optical element 100 in accordance with an embodiment of the present invention. Also, FIG. 2 schematically shows a plan view of the optical element 100 shown in FIG. 1. It is noted that FIG. 1 is a view showing a cross section taken along a line A-A in FIG. 2.

The optical element 100 in accordance with the present embodiment includes, as shown in FIG. 1 and FIG. 2, a surface-emitting type semiconductor laser 140, a light-receiving element 120, and a photodetector section 150. The photodetector element 150, the surface-emitting type semiconductor laser 140, the light-receiving element 120, and the overall structure of the optical element 100 are described below.

1.1. Photodetector Element

The photodetector element 150 detects a part of laser light emitted from the surface-emitting type semiconductor laser 140. The photodetector element 150 is provided on a substrate 10. The photodetector element 150 includes a first photoabsorption layer 151, a first contact layer 152, a second electrode 153, and a first electrode 154. The first photoabsorption layer 151 is provided on the substrate 10, and the first contact layer 152 is provided on the first photoabsorption layer 151. The first photoabsorption layer 151 and the first contact layer 152 may each have a plane configuration that is a circular shape, as shown in FIG. 2.

The substrate 10 may be composed of, for example, an n-type GaAs substrate. The first photoabsorption layer 151 may be composed of, for example, a GaAs layer in which no impurity is introduced. The first contact layer 152 may be composed of, for example, an n-type GaAs layer. The first contact layer 152 is made to be p-type by doping, for example, carbon (C).

The first electrode 154 is formed on a back surface of the substrate 10. The second electrode 153 is formed on an upper surface to the first contact layer 152. The first electrode 154 and the second electrode 153 are used for driving the photodetector element 150. The second electrode 153 is formed in a manner to surround a second contact layer 101 to be described below, and may have a plane configuration that is, for example, a ring shape.

1.2. Surface-Emitting Type Semiconductor Laser

The surface-emitting type semiconductor laser 140 is formed on the photodetector element 150. The surface-emitting type semiconductor laser 140 includes a second contact layer 101, a first mirror 102, an active layer 103, a second mirror 104, a current constricting layer 105, a third electrode 107 and a fourth electrode 109. The surface-emitting type semiconductor laser 140 has a vertical resonator. The first mirror 102, the active layer 103, the second mirror 104 and the current constricting layer 105 compose a columnar semiconductor deposited body (hereafter referred to as a “columnar section”) 130. The columnar section 130 functions as a resonator of the surface-emitting type semiconductor laser 140. The second contact layer 101 is formed above the first contact layer 152. The second contact layer 101 may be composed of, for example, an n-type GaAs layer. The first mirror 102 is formed on the second contact layer 101. The first mirror 102 may be composed of, for example, a distributed reflection type multilayer mirror of 38.5 pairs of alternately laminated n-type Al_{0.9}Ga_{0.1}As layers and n-type Al_{0.1}Ga_{0.9}As layers. It is noted that the second contact layer 101 can function as a portion of the first mirror 102. The active layer 103 is formed on the first mirror 102. The active layer 103 may be composed of GaAs well layers and A1_{0.3}Ga_{0.7}As barrier layers in which the well layers include a quantum well structure composed of three layers. The second mirror 104 is formed on the active layer 103. The second mirror 104 may be composed of, for example, a distributed reflection type multilayer mirror of 24 pairs of alternately laminated p-type Al_{0.9}Ga_{0.1}As layers and p-type Al_{0.1}Ga_{0.9}As layers. It is noted that the composition of each layer and the number of layers composing the first mirror 102, the active layer 103 and the second mirror 104 may not be particularly limited to the above.

The second mirror 104 is made to be p-type by doping, for example, carbon (C), and the first mirror 102 is made to be n-type by doping, for example, silicon (Si). Accordingly, a pin diode is formed with the p-type second mirror 104, the active layer 103 in which no impurity is doped, and the n-type first mirror 102.

It is noted that the plane configuration of the columnar section 130 in accordance with the present embodiment is circular, but the configuration thereof can be in any arbitrary shape.

The current constricting layer 105 is obtained by oxidizing a layer of AlGaAs from its side surface, in a region near the active layer 103 among the layers composing the second mirror 104. The current constricting layer 105 is formed in a ring shape. In other words, the current constricting layer 105 has a cross-sectional configuration which, when cut in a plane parallel with the substrate 10, is in a ring shape defined by circles concentric with the circular shape of the plane configuration of the columnar section 130.

The third electrode 107 and the fourth electrode 109 are used to drive the surface-emitting type semiconductor laser 140. The third electrode 107 is formed on the second contact layer 101. The third electrode 107 may be formed in a manner to surround the columnar section 130, and may have a ring-shaped plane configuration. The fourth electrode 109 is formed on the second mirror 104. The fourth electrode 109 has a ring-shaped plane configuration on the columnar section 130, as shown in FIG. 2, and has an aperture section 109a. The aperture section 109a forms an emission surface 108 from which the surface-emitting type semiconductor laser 140 emits laser light. The fourth electrode 109 may be formed above the current constricting layer 105.

It is noted that a common electrode 160 is formed on an upper surface of the third electrode 107 and the second electrode 153.

1.4. Isolation Layer

In the optical element 100 in accordance with the present embodiment, an isolation layer 170 is formed on the semiconductor element 140. In other words, the isolation layer 170 is provided between the surface-emitting type semiconductor laser 140 and a light-receiving element 120 to be described below. Concretely, as shown in FIG. 1, the isolation layer 170 is formed on the second mirror 104. In other words, the isolation layer 170 is provided between the second mirror 104 and a third contact layer 111 to be described below.

The isolation layer 170 can be formed from a high resistance layer or an insulation layer. The isolation layer 170 may be formed by laminating, for example, an undoped semi-insulating AlGaAs layer with a high Al composition on the second mirror 104 by epitaxial growth. It is noted that an AlGaAs layer with a high Al composition may be, for example, an Al_{0.9}Ga_{0.1}As layer. The isolation layer 170 can be oxidized because it contains Al. Therefore, the isolation layer 170 can become an insulation film when it is oxidized.

The isolation layer 170 is formed around the fourth electrode 109, as viewed in a plan view. More specifically, the isolation layer 170 is formed around the emission surface 108, in other words, around the fourth electrode 109. The isolation layer 170 may have a plane configuration that defines a portion of a ring shape having an aperture section concentric with the fourth electrode 109, in other words, a C-shaped configuration. In the illustrated example, the isolation layer 170 has a plane configuration that is the same as the plane configuration of the third contact layer 111. However, the isolation layer 170 may be formed with a plane configuration that is greater than the plane configuration of the third contact layer 111. Also, the isolation layer 170 is formed above the current constricting layer 105, and is not formed on the emission surface 108.

By providing the isolation layer 170 in a manner described above, the semiconductor layer 122 and the columnar section 130 can be electrically and optically isolated from each other.

1.5. Light-Receiving Element

The light-receiving element 120 receives laser light from outside. The light-receiving element 120 is provided on the isolation layer 170. The light-receiving element 120 includes a third contact layer 111, a second photoabsorption layer 112, a fourth contact layer 113, a fifth electrode 116, and a sixth electrode 115.

The third contact layer 111 is formed on the isolation layer 170. The third contact layer 111 may have a plane configuration similar to that of the isolation layer 170. The third contact layer 111 may be composed of, for example, an n-type GaAs layer. The second photoabsorption layer 112 is formed on the third contact layer 111. The second photoabsorption layer 112 may be composed of, for example, a GaAs layer in which no impurity is doped. The fourth contact layer 113 is formed on the second photoabsorption layer 112. The fourth contact layer 113 may be composed of a p-type GaAs layer.

The second photoabsorption layer 112 and the fourth contact layer 113 have similar plane configurations in the illustrated example. The second photoabsorption layer 112 and the fourth contact layer 113 are formed in a manner to surround the fourth electrode 109, and have a plane configuration that defines a portion of a ring shape having an aperture section concentric with the emission surface 108, in other words, a C-shaped plane configuration. Also, the second photoabsorption layer 112 and the fourth contact layer 113 are formed above the current constricting layer 105, and are not formed on the emission surface 108.

The fifth electrode 116 and the sixth electrode 115 are used to drive the light-receiving element 120. The fifth electrode 116 is formed on the third contact layer 111. The fifth electrode 116 is formed in a manner to surround the second photoabsorption layer 112, as viewed in a plan view. The fifth electrode 116 may have a ring-shaped plane configuration, except a region where a lead-out section extending to a pad section 109P of the fourth electrode 109 is formed, as shown in FIG. 2. In other words, the fifth electrode 116 has a C-shaped plane configuration. The sixth electrode 115 is formed on the fourth contact layer 113. The sixth electrode 115 is formed along a peripheral edge of the fourth contact layer 113, and has an aperture section. The aperture section of the sixth electrode 115 defines a light-receiving surface 117 of the light-receiving element 120. Also, the sixth electrode 115 and the fifth electrode 116 are formed with lead-out sections to be connected to electrode pads (e.g., an electrode pad 115P for the sixth electrode 115), respectively.

1.6. Overall Structure

In the optical element 100 in accordance with the present embodiment, the n-type substrate 10 and the p-type first contact layer 152 of the photodetector element 150, the n-type first mirror 102 and the p-type second mirror 104 of the surface-emitting type semiconductor laser 140, and the n-type third contact layer 111 and the p-type fourth contact layer 113 of the light-receiving element 120 form an npnpnp structure as a whole.

In the present embodiment, a case where the light-receiving element 120 and the photodetector element 150 function as pin type photodiodes is described above. However, the invention is also applicable to other types of light-receiving elements and photodetector elements in addition to pin type photodiodes. It is noted that the light-receiving elements and photodetector elements to which the invention is applicable include, for example, avalanche type photodiodes and MSM type photo diodes.

2. Operation of Optical Element

General operations of the optical element 100 in accordance with the present embodiment are described below. It is noted that the method for driving the optical element 100 described below is an example, and a variety of changes can be made without departing from the subject matter of the invention.

The photodetector element 150 has a function to monitor outputs of light generated by the surface-emitting type semiconductor laser 140. Concretely, the photodetector element 150 converts light generated by the surface-emitting type semiconductor laser 140 into electric current. With the electric current value, outputs of light generated by the surface-emitting type semiconductor laser 140 can be detected. The aforementioned function is more concretely described below.

When a voltage in a forward direction is applied to the pin diode across the third electrode 107 and the fourth electrode 109, recombination of electrons and holes occur in the active layer 103 of the surface-emitting type semiconductor laser 140, thereby causing emission of light due to the recombination. Stimulated emission occurs during the period the generated light reciprocates between the second mirror 104 and the first mirror 102, whereby the light intensity is amplified. When the optical gain exceeds the optical loss, laser oscillation occurs, whereby laser light is emitted from the lower surface of the first mirror 102, and enters the first contact layer 152 of the photodetector element 150.

Then, in the photodetector element 150, the light that entered the first contact layer 152 then enters the first photoabsorption layer 151. As a result of a part of the incident light being absorbed by the first photoabsorption layer 151, photoexcitation is caused in the first photoabsorption layer 151, and electrons and holes are generated. Then, by an electric field that is applied from outside of the device, the electrons move to the first electrode 154 and the holes move to the second electrode 153, respectively. As a result, an electric current (photoelectric current) is generated in the direction from the substrate 10 to the first contact layer 152 in the photodetector element 150. By measuring the value of the current, light output of the surface-emitting type semiconductor laser 140 can be detected.

Also, light output of the surface-emitting type semiconductor laser 140 is determined mainly by a bias voltage applied to the surface-emitting type semiconductor laser 140. In particular, light output of the surface-emitting type semiconductor laser 140 greatly changes depending on the ambient temperature of the surface-emitting type semiconductor laser 140 and the service life of the surface-emitting type semiconductor laser 140. For this reason, it is necessary for the surface-emitting type semiconductor laser 140 to maintain a predetermined level of light output.

In the optical element 100 in accordance with the present embodiment, light output of the surface-emitting type semiconductor laser 140 is monitored, and the value of voltage to be applied to the surface-emitting type semiconductor laser 140 is adjusted based on the value of electric current generated by the photodetector element 150, whereby the value of electric current that circulates within the surface-emitting type semiconductor laser 140 can be adjusted. Accordingly, a predetermined level of light output can be maintained within the surface-emitting type semiconductor laser 140. The control to feed back the light output of the surface-emitting type semiconductor laser 140 to the value of a voltage to be applied to the surface-emitting type semiconductor laser 140 can be performed with an external electronic circuit (e.g., a driver circuit not shown).

Also, the photodetector element 120 has a function to convert light (i.e., optical signal) that enters the light-receiving surface 117 from outside of the optical element 100 to electrical current (i.e., electrical signal). Based on the electrical signal, the optical signal from outside of the optical element 100 can be detected.

It is noted that a designed wavelength λ₁ of the surface-emitting type semiconductor laser 140 may be different from a designed wavelength λ₂ of the light-receiving element 120. As a result, even when light with the designed wavelength λ₂ of the light-receiving element 120 enters the surface-emitting type semiconductor laser 140, the light with the designed wavelength λ₂ attenuates in the surface-emitting type semiconductor laser 140, such that the light is prevented from entering the photodetector element 150. Also, when the designed wavelength λ₁ of the surface-emitting type semiconductor laser 140 is different from the designed wavelength λ2 of the light-receiving element 120, the optical element 100 can be used for wavelength division multiplex (WDM). In this manner, by including the surface-emitting type semiconductor laser 140, the light-receiving element 120 and the photodetector element 150 in the single optical device 100, the device can be miniaturized and its manufacturing cost can be reduced.

3. Method for Manufacturing Optical Element

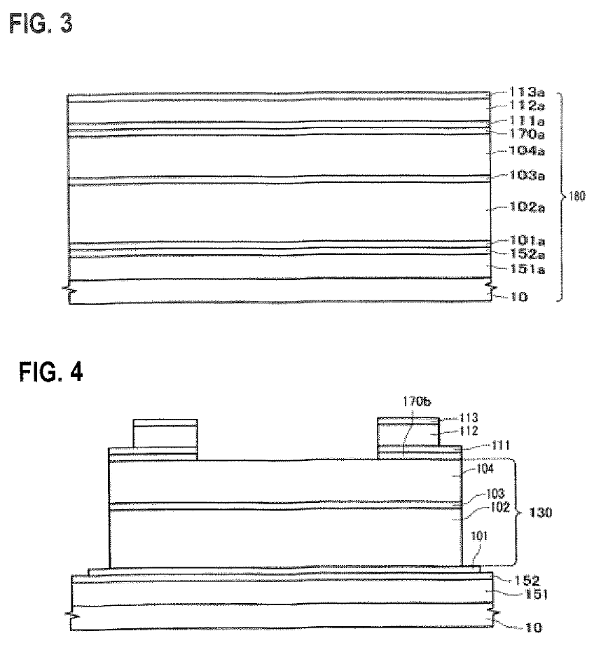

Next, an example of a method for manufacturing an optical element 100 in accordance with an embodiment of the invention is described with reference to FIG. 3 through FIG. 5. FIGS. 3 through 5 are cross-sectional views schematically showing steps of the method for manufacturing the optical element shown in FIG. 1 and FIG. 2, which correspond to the cross-sectional view shown in FIG. 1, respectively.

(1) First, on a surface of a semiconductor substrate 10 composed of n-type GaAs, a semiconductor multilayer film 180 is formed by epitaxial growth while varying the composition, as shown in FIG. 3. As a concrete example, the semiconductor multilayer film is formed from, for example, a first photoabsorption layer 151a composed of a GaAs layer in which no impurity is doped, a first contact layer 152a composed of a p-type GaAs layer, a second contact layer 101a composed of an n-type GaAs layer, a first mirror 102a of 38.5 pairs of alternately laminated n-type Al_{0.9}Ga_{0.1}As layers and n-type Al_{0.1}Ga_{0.9}As layers, an active layer 103a composed of GaAs well layers and Al_{0.3}Ga_{0.7}As barrier layers in which the well layers include a quantum well structure composed of three layers, a second mirror 104a of 24 pairs of alternately laminated p-type Al_{0.9}Ga_{0.1}As layers and p-type Al_{0.1}Ga_{0.9}As layers, an isolation layer 170a composed of an Al_{0.9}Ga_{0.1}As layer, a third contact layer 111a composed of an n-type GaAs layer, a second photoabsorption layer 112a composed of a GaAs layer in which no impurity is doped, and a fourth contact layer 113a composed of a p-type GaAs layer. These layers are successively laminated on the substrate 10, whereby the semiconductor multilayer film 180 is formed.

When growing the second mirror 104a, at least one layer adjacent to the active layer 103a may be formed from an AlAs layer or an AlGaAs layer, which is later oxidized and becomes a current constriction layer 105. The Al composition of the AlGaAs layer that becomes to be the current constricting layer 105 is, for example, 0.95 or higher. In the present embodiment, the Al composition of the AlGaAs layer means an aluminum (Al) composition with respect to III-group elements. The Al composition of the AlGaAs layer may vary from 0 to 1. In other words, the AlGaAs layer includes a GaAs layer (when the Al composition is 0) and an AlAs layer (when the Al composition is 1).

The temperature at which the epitaxial growth is conducted is appropriately decided depending on the growth method, the kind of raw material, the type of the substrate 10, and the kind, thickness and carrier density of the semiconductor multilayer film 180 to be formed, and in general may preferably be 450° C.-800° C. Also, the time required for conducting the epitaxial growth is appropriately decided like the temperature. Also, a metal-organic vapor phase growth (i.e., MOVPE: Metal-Organic Vapor Phase Epitaxy) method, a MBE method (Molecular Beam Epitaxy) method, or a LPE (Liquid Phase Epitaxy) method can be used as a method for the epitaxial growth.

(2) Next, the semiconductor multilayer film 180 is patterned by using known lithography technique and etching technique. As a result, as shown in FIG. 4, a second contact layer 101, a columnar section 130, an isolation layer 170b, a third contact layer 111, a second photoabsorption layer 112, and a fourth contact layer 113 are formed.

In the patterning steps, the sequence in forming the aforementioned layers is not particularly limited.

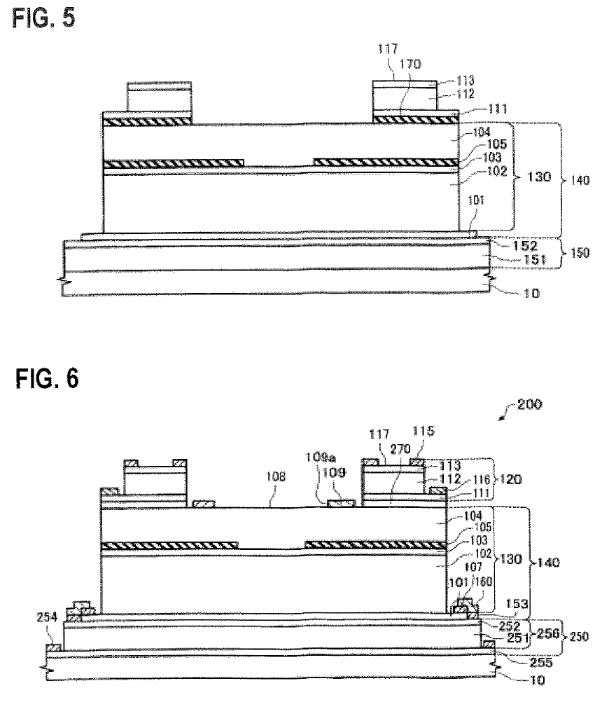

(3) Next, the substrate 10 on which the second contact layer 101, the columnar section 130, the isolation layer 170b, the third contact layer 111, the second photoabsorption layer 112, and the fourth contact layer 113 are formed through the aforementioned steps is placed in, for example, a water vapor atmosphere at about 400° C. As a result, the aforementioned layer with a high Al composition among the second mirror 104 and the isolation layer 170b are oxidized from their side surface, whereby a current constricting layer 105 and an isolation layer 170 are formed (see FIG. 5).

The oxidation rate depends on the furnace temperature, the amount of water vapor supply, and the Al composition and film thickness of a layer to be oxidized. In the surface-emitting type semiconductor laser 140 equipped with the current constricting layer 105 that is formed by oxidation, when driven, a current circulates only in a portion where the current constricting layer 105 is not formed (a portion that is not oxidized). Accordingly, in the process for forming the current constricting layer 105 by oxidation, the range of the current constricting layer 105 to be formed may be controlled, whereby the current density can be controlled. It is noted that the film thickness of the isolation layer 170b may preferably be greater than the film thickness of a layer for forming the current constricting layer 105.

Also, the diameter of a circular section where the current constricting layer 105 is not formed (i.e., a section that is not oxidized) may preferably be adjusted so that light emitted from the surface-emitting type semiconductor laser 140 would not enter the second photoabsorption layer 112. As a result, the second photoabsorption layer 112 can be prevented from absorbing light emitted from the surface-emitting type semiconductor laser 140.

(4) Next, as shown in FIG. 1, a first electrode 154, a second electrode 153, a third electrode 107, a fourth electrode 109, a fifth electrode 116 and a sixth electrode 115 are formed. Further, a common electrode 160 is formed after the second electrode 153 and the third electrode 107 are formed.

First, before forming each of the electrodes, an electrode forming region where the corresponding electrode is formed may be washed by using a plasma treatment method or the like if necessary. By this, a device with more stable characteristics can be formed.

Next, a single layer or a laminated film of layers (not shown) of conductive material for forming each of the electrodes is formed by using, for example, a vacuum deposition method. Next, by using a known lift-off method, portions of the layer or film other than specified locations are removed, whereby electrodes are formed at desired regions.

Then, an anneal treatment is conducted in, for example, a nitrogen atmosphere, if necessary. The anneal treatment may be conducted, for example, around 400° C. The anneal treatment may be conducted for, for example, about 3 minutes.

The aforementioned process may be conducted for each of the electrodes, or the plural electrodes may be formed at the same time. It is noted that each of the second electrode 153, the third electrode 107 and the sixth electrode 115 is formed from a laminated film of layers of, for example, an alloy of gold (Au) and germanium (Ge), and gold (Au). Each of the first electrode 154, the fourth electrode 109 and the fifth electrode 116 is formed from a laminated film of layers of, for example, platinum (Pt), titanium (Ti), and gold (Au). The common electrode 160 is formed from a laminated film of layers of, for example, chrome (Cr) and gold (Au). It is noted that the materials for the electrodes are not limited to those described above, and other known metals, alloys and a laminated film of layers of these metals and alloys may be used.

By the steps described above, the optical element 100 in accordance with the present embodiment is obtained, as shown in FIG. 1 and FIG. 2. In this manner, by manufacturing all of the light-receiving element 120, the surface-emitting type semiconductor laser 140 and the optical element 150 with the process in which patterning is conducted after epitaxial growth of layers on the substrate, the optical element 100 can be formed with high device reliability and favorable yield. Also, miniaturization of the optical element 100 can be achieved.

4. In the optical element 100 in accordance with the present embodiment, because the optical element 150 is formed below the surface-emitting type semiconductor laser 140, the optical element 150 is not formed on an optical path of laser light that is emitted from the emission surface 108 of the surface-emitting type semiconductor laser 140. Accordingly, the photodetector element 150 can reduce the impact that may affect the optical characteristics of the surface-emitting type semiconductor laser 140. Also, because the light-receiving element 120 is formed around the emission surface 108, the light-receiving element 120 is not formed on an optical path of laser light that is emitted from the emission surface 108 of the surface-emitting type semiconductor laser 140. Accordingly, the light-receiving element 120 can reduce the impact that may affect the optical characteristics of the surface-emitting type semiconductor laser 140. Also, in the optical element 100 in accordance with the present embodiment, the isolation layer 170 is formed around the emission surface 108, as viewed in a plan view, the isolation layer 170 is not formed on an optical path of laser light that is emitted from the emission surface 108 of the surface-emitting type semiconductor laser 140. Accordingly, the isolation layer 170 can reduce the impact that may affect the optical characteristics of the surface-emitting type semiconductor laser 140.

Moreover, the isolation layer 170 and the light-receiving element 120 are formed only above the current constricting layer 105, and therefore are not formed on an optical path of laser light that is emitted from an inner side of the current constricting layer 105. Accordingly, the isolation layer 170 and the light-receiving element 120 can reduce the impact that may affect the optical characteristics of the surface-emitting type semiconductor laser 140.

5. Modified Example

Next, modified examples of the embodiment of the invention are described.

5.1. First Modified Example

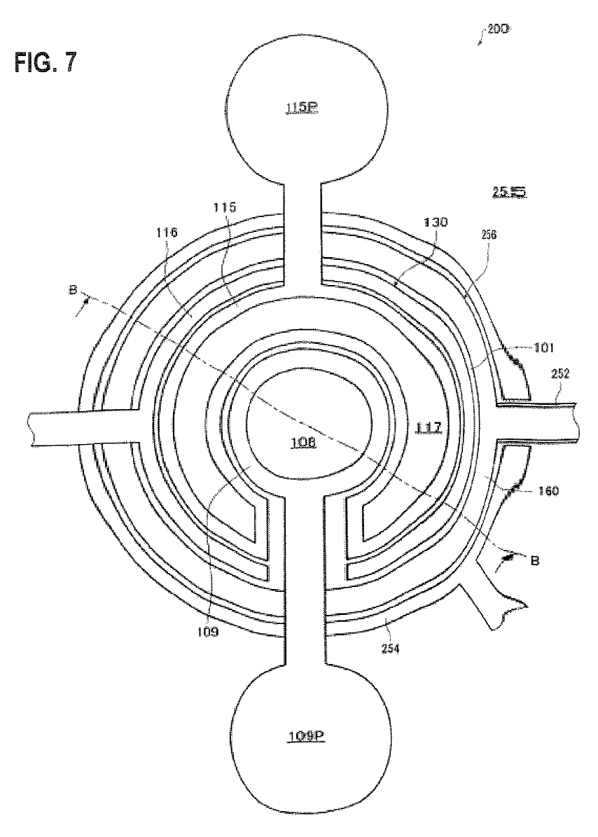

FIG. 6 is a schematic cross-sectional view of an optical element 200 in accordance with a first modified example of the embodiment of the invention. FIG. 7 is a schematic plan view of the optical element 200 in accordance with the first modified example. It is noted that FIG. 6 is a cross-sectional view taken along a line B-B of FIG. 7.

The optical element 200 in accordance with the first modified example has a first electrode 254 formed above a substrate 10, and therefore is different from the optical element 100 in which the first electrode 154 is formed at the back surface of the substrate 10. In other words, the optical element 200 is different from the optical element 100 in its structure of a photodetector element 250.

The photodetector element 250 has a fifth contact layer 255 formed on the substrate 10, a first photoabsorption layer 251 formed on the fifth contact layer 255, and a first contact layer 252 formed on the first photoabsorption layer 251. Moreover, the photodetector element 250 has a first electrode 254 formed on the fifth contact layer 255, and a second electrode 153 formed on the first contact layer 252. The first electrode 254 is formed in a manner to surround the first photoabsorption layer 251 as viewed in a plan view.

In the case of the optical element 100, when a substrate composed of a material that is difficult to function as a contact layer because of the substrate not containing an impurity is used, an electrode may not be formed on a back surface of the substrate. Therefore, even when such a substrate is used, a contact layer doped with an impurity may be formed on the substrate in accordance with the first modified example, whereby the first electrode 254 can be formed, not on a back surface, but on an upper surface of the substrate. In the optical element 200, for example, a GaAs substrate may be used as the substrate 10. As the fifth contact layer 255, for example, an n-type GaAs layer may be used.

Other details of the structure and operations of the optical element 200 in accordance with the first modified example are substantially the same as the structure and operations of the optical element 100 in accordance with the embodiment described above, and therefore their description is omitted.

5.2. Second Modified Example

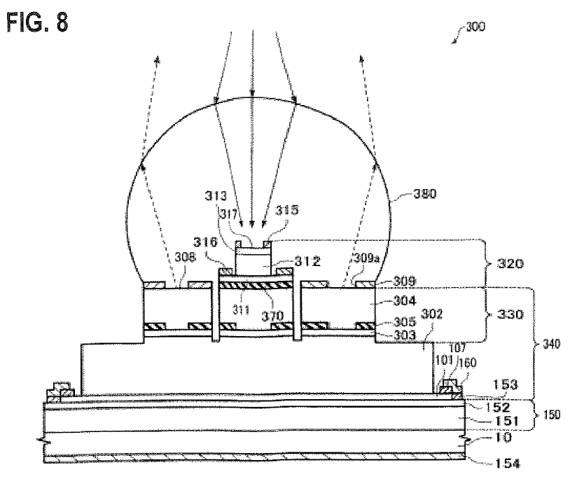

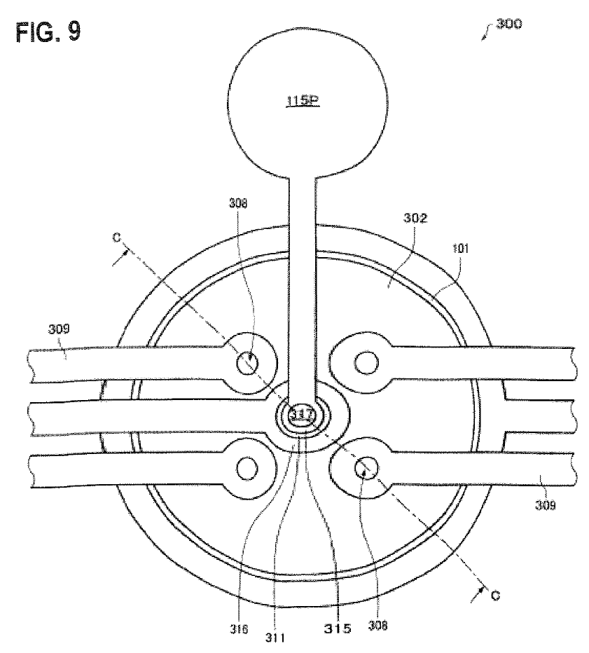

FIG. 8 is a schematic cross-sectional view of an optical element 300 in accordance with a second modified example of the embodiment of the invention. FIG. 9 is a schematic plan view of the optical element 300 in accordance with the second modified example. It is noted that FIG. 8 is a cross-sectional view taken along a line C-C shown in FIG. 9. Also, in FIG. 9, illustration of an optical member 380 to be described below is omitted.

The optical element 300 in accordance with the second modified example has an emission surface 308 formed around a light-receiving element 320, and therefore is different from the optical element 100 having the light-receiving element 120 formed around the emission surface 108. Also, the optical element 300 is different from the optical element 100 in that it has an optical member 380 formed on the emission surface 308.

The optical element 300 includes a light-receiving element 320, an isolation layer 370, and a surface-emitting type semiconductor laser 340. The surface-emitting type semiconductor laser 340 has a columnar section 330 that functions as a resonator. The columnar section 330 is formed from a portion of a first mirror 302, an active layer 303, a current constricting layer 305, and a second mirror 304. The surface-emitting type semiconductor laser 340 further includes a fourth electrode 309 formed on the second mirror 304. The surface-emitting type semiconductor laser 340 may have a plurality of emission surfaces 308 as shown in FIG. 9, or an emission surface in a ring shape that surrounds the light-receiving element 320. The fourth electrode 309 is formed on the second mirror 304. The fourth electrode 309 has a portion in a ring-shaped plane configuration as shown in FIG. 9, and its aperture section 309a forms the emission surface 308. Also, the surface-emitting type semiconductor laser 340 may have a plurality of fourth electrodes 309, as shown in FIG. 8 and FIG. 9.

The isolation layer 370 is formed inside the fourth electrodes 309, as shown in FIG. 8. The isolation layer 370 may have a plane configuration that is, for example, a circular shape.

The light-receiving element 320 has a third contact layer 311, a second photoabsorption layer 312, a fourth contact layer 313, a fifth electrode 316, and a sixth electrode 315. The third contact layer 311 may have a plane configuration that is similar to that of the isolation layer 370. The second photoabsorption layer 312 and the fourth contact layer 313 are formed above the third contact layer 311, and may have a circular plane configuration. The fifth electrode 316 is formed in a manner to surround the second photoabsorption layer 312. The fifth electrode 316 may have a ring shaped plane configuration. The sixth electrode 315 is formed along a peripheral edge section of the fourth contact layer 313, and may have a ring shaped plane configuration. The sixth electrode 315 has an aperture section, and the aperture section defines a light receiving surface 317.

The optical element 300 further includes an optical member 380. The optical member 380 can reduce the emission angle of laser light emitted from the surface-emitting type semiconductor laser 340. Also, the optical member 380 can focus light from outside, and bring the light incident upon the light receiving surface 317. The optical member 380 in accordance with the third modified example can function as a lens. The optical member 380 may be formed through hardening a liquid material that can be cured by energy such as heat, light or the like. The optical member 380 may be composed of ultraviolet setting type resin, such as, acrylic resin and epoxy resin, a thermosetting type resin, such as, polyimide resin or the like. The optical member 380 has a cut spherical shape as shown in FIG. 8. When the optical member 380 has a cut spherical shape, it can function as a lens or a polarizer element. It is noted that the “cut spherical shape” refers to a configuration in which a sphere is cut in a single plane, and the sphere includes a perfect sphere and a shape similar to a sphere.

The optical member 380 may be formed through jetting droplets containing the aforementioned liquid material (e.g., resin) of the optical member 380 toward the light-receiving surface 317 and the emission surface 308 by using, for example, an ink jet method. Before jetting the aforementioned droplets, a liquid repelling treatment or a lyophilic treatment may be applied to upper surfaces of the light-receiving element 320 and the surface-emitting type semiconductor laser 340, and a dam member, a base member or the like for damming the droplets may be formed on the upper surfaces. After the droplets are jetted on the upper surfaces, energy rays such as ultraviolet rays may be irradiated to harden the deposited resin.

Other details of the structure and operations of the optical element 300 in accordance with the second modified example are substantially the same as the structure and operations of the optical element 100 in accordance with the embodiment described above, and therefore their description is omitted.

5.3. Third Modified Example

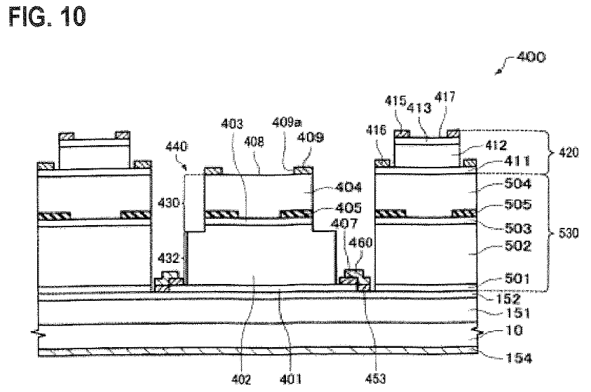

FIG. 10 is a schematic cross-sectional view of an optical element 400 in accordance with a third modified example of the embodiment of the invention. The optical element 400 in accordance with the third modified example has a light-receiving element 420 that is formed around a columnar section of its surface-emitting type semiconductor laser 440, and therefore is different from the optical element 100 that has the light-receiving element 120 formed on the columnar section 130. The optical element 400 is further different from the optical element 100 in that it includes a base section 530.

The surface-emitting type semiconductor laser 440 includes a second contact layer 401, a columnar section 430, and a columnar section 432. The columnar section 432 includes a portion of a first mirror 402, and the columnar section 430 includes another portion of the first mirror 402, an active layer 403, a second mirror 404, and a current constricting layer 405. The columnar section 430 has a plane configuration that is, for example, a circular shape. Also, the surface-emitting type semiconductor laser 440 further includes a fourth electrode 409 and a third electrode 407. The fourth electrode 409 is formed along a peripheral edge section of the columnar section 430, has an aperture section 409a, and has a plane configuration that is, for example, a ring shape. The aperture section 409a of the fourth electrode 409 defines an emission surface 408. A second electrode 453 and the third electrode 407 are formed in a manner to surround the circumference of the columnar section 432, and have a plane configuration that is, for example, a ring shape. A common electrode 460 is formed on upper surfaces of the second electrode 453 and the third electrode 407. The columnar section 430 and the columnar section 432 are formed by the patterning technique described above.

The base section 530 is formed around the circumference of the columnar section 430, as shown in FIG. 10. The base section 530 is formed from a multilayer film similar to the semiconductor multilayer film that composes the columnar section 430. Concretely, the base section 530 includes a second contact layer 501, a first mirror 502, an active layer 503, a second mirror 504, and a current constricting layer 505. A light-receiving element 420 is formed on an upper surface of the base section 530. By this, the optical coupling efficiency of the light-receiving element 420 can be made better, compared to a light-receiving element without the base section 530.

The light-receiving element 420 includes a third contact layer 411, a second photoabsorption layer 412, a fourth contact layer 413, a sixth electrode 415, a fifth electrode 416, and a light-receiving surface 417. As the plane configuration of each of the layers composing the light-receiving element 420 may be similar to that of the optical element 100 described above, its description is omitted.

Moreover, the optical element 400 is different from the optical element 100 in that it does not have an isolation layer. The optical element 420 is formed on the base section 530, but not on the columnar section 430. Therefore, it is not necessary to isolate electrically the light-receiving element 420 from the base section 530 that is not provided with an electrode.

Some of the embodiments of the invention are described above in detail. However, those skilled in the art should readily understand that many modifications can be made without departing in substance from the novel matter and effects of the invention. Accordingly, those modified examples are also included in the scope of the invention.

For example, in the embodiments described above, interchanging the p-type and n-type characteristics of each of the semiconductor layers does not deviate from the subject matter of the invention. Also, in the optical element 100 of the embodiment described above, AlGaAs type materials are used. However, depending on the oscillation wavelength to be generated, other materials, such as, for example, AlGaInAs type, GaInNAs type, and InGaAs type semiconductor materials can be used.

What is claimed is:

1. An optical element comprising:
a surface-emitting type semiconductor laser;
a photodetector element that detects a part of laser light emitted from the surface-emitting type semiconductor laser; and
a light-receiving element that receives laser light from outside, wherein
the photodetector element has a first photoabsorption layer formed above a substrate,
the surface-emitting type semiconductor laser has a first mirror formed above the first photoabsorption layer, an active layer formed above the first mirror, and a second mirror formed above the active layer, and
the light-receiving element has a second photoabsorption layer formed above the second mirror.

2. An optical element according to claim 1, wherein the second photoabsorption layer is formed around an emission surface of the surface-emitting type semiconductor laser.

3. An optical element according to claim 1, wherein the surface-emitting type semiconductor laser further includes an electrode having an aperture section above the second mirror, and the second photoabsorption layer is formed around the electrode.

4. An optical element according to claim 1, wherein the surface-emitting type semiconductor laser further includes a current constricting layer in one of the first mirror and the second mirror, and the second photoabsorption layer is formed above the current constricting layer.

5. An optical element according to claim 1, wherein the surface-emitting type semiconductor laser has a columnar section formed from a first mirror, an active layer and a second mirror and functions as a resonator, and the light-receiving element is formed above the columnar section.

6. An optical element according to claim 1, wherein the surface-emitting type semiconductor laser has a columnar section formed from a first mirror, an active layer and a second mirror and functions as a resonator, and the light-receiving element is formed around the columnar section as viewed in a plan view.

7. An optical element according to claim 6, further comprising a base section that is formed around the columnar section and includes layers in common with the first mirror, the active layer and the second mirror, and the light-receiving element is formed above the base section.

8. An optical element according to claim 1, comprising an emission surface around the second photoabsorption layer.

9. An optical element according to claim 1, wherein the surface-emitting type semiconductor laser has an electrode having an aperture section above the second mirror, and the light-receiving element is formed at the aperture section of the electrode.

10. An optical element according to claim 9, further comprising an optical member formed above the light-receiving element.

11. An optical element according to claim 9, further comprising an optical member formed above the emission surface of the surface-emitting type semiconductor laser.

12. An optical element according to claim 1, further comprising a common electrode that drives the photodetector element and the surface-emitting type semiconductor laser.

13. An optical element according to claim 1, wherein a designed wavelength of laser light that is emitted by the surface-emitting type semiconductor laser is different from a designed wavelength of laser light that is received by the light-receiving element.

14. An optical element according to claim 1, further comprising an isolation layer formed between the second mirror and the second photoabsorption layer.

15. A method for manufacturing an optical element having a surface-emitting type semiconductor laser, a photodetector element that detects a part of laser light emitted from the surface-emitting type semiconductor laser, and a light-receiving element that receives laser light from outside, the method comprising the steps of:
laminating layers of a semiconductor multilayer film for forming, from a substrate side, a first photoabsorption layer included in the photodetector element, a first mirror, an active layer and a second mirror included in the surface-emitting type semiconductor laser, and a second photoabsorption layer included in the light-receiving element;
forming an emission surface by exposing an upper surface of the surface-emitting type semiconductor laser by patterning the second photoabsorption layer; and
forming a resonator by patterning the layers for forming the first mirror, the active layer and at least a part of the second mirror.
